(19) United States
(12) Patent Application Publication
(10) Pub. No.: US 2005/0022930 A1
(43) Pub. Date: Feb. 3, 2005

(54) Substrate treatment apparatus, substrate treatment method and substrate manufacturing method

(76) Inventors: Yoshihiro Moriguchi, Hiratsuka-shi (JP); Ryo Izaki, Kanagawa-ken (JP); Yoshitomo Yasuike, Kanagawa-ken (JP); Takao Kamaishi, Hadano-shi (JP); Takahisa Ishida, Hadano-shi (JP)

Correspondence Address: MAYER, FORTKORT & WILLIAMS, PC, 251 NORTH AVENUE WEST, 2ND FLOOR, WESTFIELD, NJ, 07090, US

(21) Appl. No.: 10/813,926

(22) Filed: Mar. 31, 2004

(30) Foreign Application Priority Data
Apr. 17, 2003 (JP) JP 2003-112403
Apr. 17, 2003 (JP) JP 2003-112404

(51) Int. Cl. C23F 1/00

(52) U.S. Cl. 156/345.11

(57) ABSTRACT

Above a substrate mounted on rollers, an upper board is prepared a predetermined distance apart from the substrate. A pipe fills a space between the upper board and the substrate with washing water by supplying the washing water at a predetermined flow rate. A washing water layer is formed evenly on an upper surface of the substrate when the substrate passes below the upper board. Below the substrate, a lower board is prepared a predetermined distance apart from the substrate. A pipe fills a space between the lower board and the substrate with the washing water by supplying the washing water at a predetermined flow rate. A washing water layer is formed evenly on a lower surface of the substrate when the substrate passes above the lower board. The air emitted from an air knife is sprayed to the upper/lower surface of the substrate slantingly at a predetermined incident angle in an opposite direction of a substrate moving direction. The washing water is pushed away and removed from the upper/lower surface of the substrate.

### FIELD OF THE INVENTION

The present invention relates to a substrate treatment apparatus and a substrate treatment method for drying a substrate by spraying the air to the substrate using an air knife, and a substrate manufacturing method employing them. It especially relates to the substrate treatment apparatus and the substrate treatment method suitable for drying the large-size substrate or the substrate having the water repellency strongly on its surface, and the substrate manufacturing method employing them.

### BACKGROUND OF THE INVENTION

In a manufacturing process of a panel substrate for a flat panel display, such as a liquid crystal display, a plasma display and the like, a chemical liquid treatment, such as development, etching, etc., is performed in order to form circuit patterns, a color filter, etc. on the substrate. Also in a manufacturing process of a semiconductor device, the chemical liquid treatment, such as development, etching, etc., is performed in order to form the circuit patterns, etc. on a substrate, such as a semiconductor wafer, etc. And before or after the chemical liquid treatment, it is required to wash the substrate using the washing water (pure water) and dry the substrate after washing. In many cases, a series of these processes including washing and drying of the substrate is performed while moving the substrate using the carry equipment, such as a roller conveyer and the like. And the substrate is usually dried by spraying the air to the substrate using an air knife so that a treatment liquid, such as the washing water, etc., is pushed away and removed from a surface of the substrate.

The Japanese Patent Laid-Open 2002-252200 describes a technology for performing the series of the processes to the substrate while moving the substrate. And the Japanese Patent Laid-Opens 2001-50660 and 2001-284777 describe a technology for drying the substrate using the air knife.

In a drying process using the air knife, if the treatment liquid, such as the washing water, etc., is distributed unevenly on the surface of the substrate, the treatment liquid will be removed unevenly so that drying stains will be generated on the surface of the substrate. For this reason, it was conventionally required to form a treatment liquid layer evenly on the surface of the substrate before drying in order to dry the substrate evenly using the air knife. However, since the area of the substrate becomes larger due to the enlargement of the flat panel display in recent years, a large amount of the treatment liquid is needed in order to form the treatment liquid layer evenly on the surface of the substrate.

Moreover, among the substrates washed and dried during the manufacturing processes of various displays or the semiconductor devices, there are some substrates having the water repellency strongly on their surfaces to repel the washing water (pure water). For example, in a manufacturing process of the color filter of the liquid crystal display, a black matrix for shutting out the light, coloring patterns of RGB for displaying colors, a transparent protection film for protecting the coloring patterns and transparent film electrodes for driving the liquid crystal are formed on a glass substrate. Especially, resin films for forming the black matrix and the coloring patterns have the water repellency strongly among these. For this reason, the surface of the substrate has the water repellency strongly when the black matrix or the coloring patterns are formed.

It is difficult to form a washing water layer evenly on the surface of the substrate, which has the water repellency strongly, so that areas without the washing water layer appear on the surface of the substrate. Then, drops of the washing water, which are blown away with the air from the air knife, adhere to the areas without the washing water layer and result in drying stains called watermark. Although such watermarks had been conventionally permitted to some extent, they can not be disregarded anymore since they cause a problem of appearance and surface resistance variations when the pitch of the circuit patterns, which are formed on the surface of the substrate, becomes finer and finer.

Moreover, for performing the series of the processes to the substrate while moving the substrate, a sloping carry system, which slopes the substrate at a certain angle from the horizontal while moving the substrate, is known (the Japanese Patent Laid-Open 2001-108977). Especially in a washing process using the sloping carry system, the high washing effect is obtained since the treatment liquid, such as a developing solution, etching solution, etc., does not stagnate on the surface of the substrate but it is efficiently replaced with the washing water. Furthermore, the high foreign matter removal effect is obtained since the washing water also does not stagnate on the surface of the substrate so that foreign matters, which float out from the surface of the substrate, hardly adhere to the surface of the substrate again.

For the color filter mentioned above as an example, the washing process using the sloping carry system is strongly required since the resin films come off easily and many foreign matters remain as a residue when washing the substrate in a horizontal state. However, when the substrate, which has the water repellency strongly on its surface, is dried using the air knife while moving the substrate by the conventional sloping carry system, most of the washing water, which is supplied to the surface of the substrate, flows out of the surface of the sloped substrate before drying, and few water remains on the surface of the substrate as small drops. Then, the remained small drops are moved on the surface of the substrate by the air sprayed from the air knife. For this reason, there was a problem that traces of the small drops, which were moved on the surface of the substrate, result in line-shape stains. Moreover, there was a problem that the foreign matters remain along the traces of the small drops, which were moved on the surface of the substrate.

### SUMMARY OF THE INVENTION

The purpose of the present invention is to reduce an amount of the treatment liquid used when drying the substrate using the air knife.

Another purpose of the present invention is to prevent the watermarks being generated and dry the substrate evenly without the drying stains when drying the substrate using the air knife.

Another purpose of the present invention is to dry the surface of the substrate, which has the water repellency strongly on its surface, evenly without the drying stains while obtaining the high washing effect and the high foreign matter removal effect by the sloping carry system.

Another purpose of the present invention is to reduce the foreign matters remained on the surface of the substrate, which has the water repellency strongly on its surface, while obtaining the high washing effect and the high foreign matter removal effect by the sloping carry system.

Another purpose of the present invention is to shorten the drying time and reduce the drying stains when drying the substrate using the air knife.

Another purpose of the present invention is to manufacture a high quality substrate having few drying stains and few foreign matters on its surface.

A feature of the present invention is preparing the first flat component a predetermined distance apart above the substrate, filling a space between the first flat component and the substrate with the treatment liquid, and spraying the air to the upper surface of the substrate, which passes below the first flat component, from the first air knife while moving the substrate.

A further feature of the present invention is preparing the second flat component a predetermined distance apart below the substrate, filling a space between the second flat component and the substrate with the treatment liquid, and spraying the air to the lower surface of the substrate, which passes above the second flat component, from the second air knife.

By preparing the first/second flat component the predetermined distance apart above/below the substrate and filling the space between the first/second flat component and the substrate with the treatment liquid, it becomes possible to form the treatment liquid layer evenly on the upper/lower surface of the substrate using a less amount of the treatment liquid. Moreover, since the upper/lower surface of the substrate is covered by the first/second flat component, the drops of the treatment liquid, which are blown away with the air from the first/second air knife, do not adhere to the upper/lower surface of the substrate. Therefore, it becomes possible to prevent the watermarks being generated.

Another feature of the present invention is spraying the air from the air knife to the surface of the substrate slantingly at a predetermined incident angle, and supplying the treatment liquid near from the air knife to the surface of the substrate slantingly at a predetermined incident angle in an opposite direction of the air from the air knife so as to form the treatment liquid layer on the surface of the substrate while moving the substrate, which has the water repellency strongly on its surface, with the substrate sloped at a predetermined angle from the horizontal.

A boundary of the formed treatment liquid layer appears at a position, where the power of a flow of the supplied treatment liquid to push the layer, the power of the layer to move along a slope of the substrate and the power of the air from the air knife to push the layer away are balanced. Beside the boundary of the treatment liquid layer on the surface of the substrate, a side in a substrate moving direction becomes a dry area, where the treatment liquid layer is pushed away and removed by the air from the air knife. On the other hand, in a non-dry area in an opposite side, the treatment liquid layer is always formed with the supplied treatment liquid. Therefore, even if the substrate has the water repellency strongly on its surface, the line-shape stains will not be generated unlike before since the treatment liquid layer has being formed on the surface of the substrate just before drying. Moreover, the foreign matters do not remain unlike before along the traces of the small drops moved. And the high washing effect and the high foreign matter removal effect are obtained by sloping the substrate at the predetermined angle from the horizontal while moving the substrate.

By drying the substrate using the present invention, it becomes possible to reduce the drying stains and the foreign matters on the surface of the substrate and manufacture a high quality substrate.

### BRIEF DESCRIPTION OF THE DRAWINGS

FIG. 1 is a side view including some sections showing an example of the substrate treatment apparatus according to the present invention.

FIG. 2 is a side view including some sections showing another example of the substrate treatment apparatus according to the present invention.

FIG. 3 is a side view including some sections showing another example of the substrate treatment apparatus according to the present invention.

FIG. 4 shows an outline of another example of the substrate treatment apparatus according to the present invention.

FIG. 5 is a side view including some sections showing another example of the substrate treatment apparatus according to the present invention.

FIG. 6 is a side view including some sections showing another example of the substrate treatment apparatus according to the present invention.

FIG. 7 is a side view including some sections showing another example of the substrate treatment apparatus according to the present invention.

FIG. 8 shows another example of the substrate treatment apparatus according to the present invention, wherein (a) shows a top view and (b) shows a side view.

FIG. 9 shows an operation of the substrate treatment apparatus shown in FIG. 8.

FIG. 10 shows another example of the substrate treatment apparatus according to the present invention, wherein (a) shows an outline and (b) shows a front view.

FIG. 11 shows an operation of the substrate treatment apparatus shown in FIG. 10.

FIG. 12 is a side view showing another example of the substrate treatment apparatus according to the present invention.

### DETAILED DESCRIPTION OF PREFRERRED EMBODIMENTS

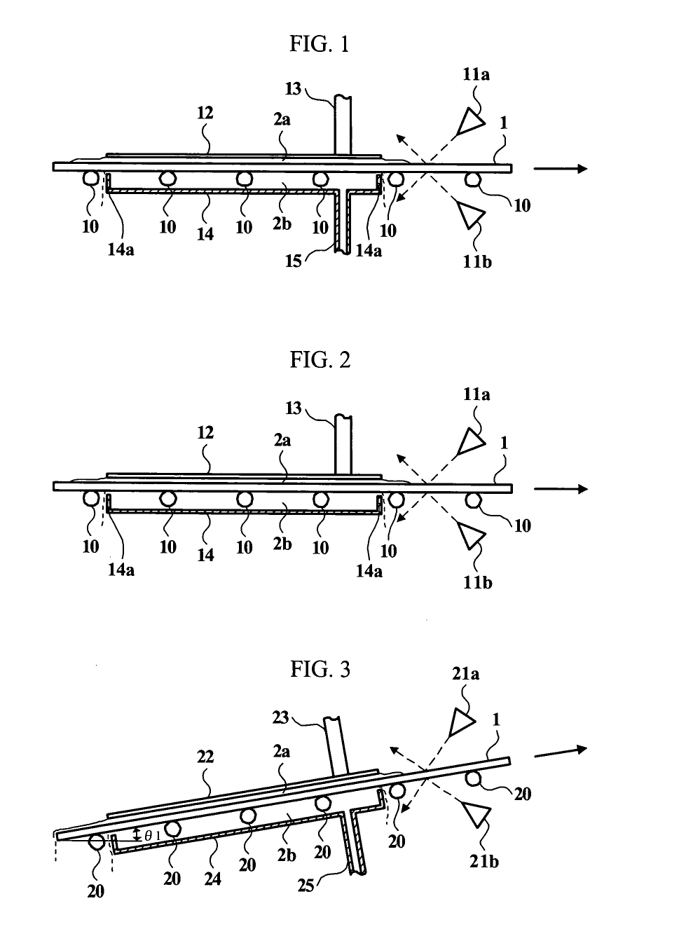

Further details are explained below with the help of examples illustrated in the attached drawings. FIG. 1 is a side view including some sections showing an example of the substrate treatment apparatus according to the present invention. This example moves a substrate horizontally. The substrate treatment apparatus comprises a plurality of rollers 10, air knives 11a and 11b, an upper board 12, a pipe 13, a lower board 14 and a pipe 15.

A substrate 1 is mounted on the rollers 10 and moved in a substrate moving direction shown by an arrow with the rotation of the rollers 10. Each roller 10 is arranged a certain distance apart each other in the substrate moving direction and rotated at a predetermined speed by the drive equipment, which is not illustrated. Each roller 10 is installed at the same height horizontally so that the rollers 10 move the substrate 1 horizontally.

Above the substrate 1 mounted on the rollers 10, the upper board 12 is prepared through a width of the substrate 1 in a direction perpendicular to the substrate moving direction, wherein the upper board 12 is a predetermined distance apart from the substrate 1 and in parallel with the substrate 1. On the upper board 12, the pipe 13 is installed at a certain position, which is shifted to the substrate moving direction from the center of the upper board 12. The pipe 13 fills a space between the upper board 12 and the substrate 1 with the washing water 2a by supplying the washing water at a predetermined flow rate. Thereby, a washing water layer is formed evenly on an upper surface of the substrate 1 when the substrate 1 passes below the upper board 12.

Below the substrate 1 mounted on the rollers 10, the lower board 14 is prepared through the width of the substrate 1 in the direction perpendicular to the substrate moving direction, wherein the lower board 14 is a predetermined distance apart from the substrate 1 and in parallel with the substrate 1. In this example, a space between the lower board 14 and the substrate 1 is bigger than a diameter of the rollers 10, and the lower board 14 is located under the rollers 10. And the rollers 10 located over the lower board 14 are surrounded by walls 14a, which are prepared at edges of the lower board 14. On the lower board 14, the pipe 15 is installed at a certain position, which is shifted to the substrate moving direction from the center of the lower board 14. The pipe 15 fills the space between the lower board 14 and the substrate 1 with the washing water 2b by supplying the washing water at a predetermined flow rate. Thereby, a washing water layer is formed evenly on a lower surface of the substrate 1 when the substrate 1 passes above the lower board 14.

Moreover, above the substrate 1 mounted on the rollers 10, the air knife 11a is prepared through the width of the substrate 1 in the direction perpendicular to the substrate moving direction, wherein the air knife 11a is near the upper board 12 and in parallel with the substrate 1. And below the substrate 1 mounted on the rollers 10, the air knife 11b is prepared in the same way. The air knives 11a and 11b are constituted of a long casing, for example, wherein a pressure room is formed inside the casing and a slit-shape air passage led to the pressure room is prepared through it length. The air is supplied to the air knives 11a and 11b from the air supply equipment, which is not illustrated, and the air knives 11a and 11b emit the air from an end of the air passage evenly through its length. As shown by arrows of a broken line in the figure, the air, which is emitted from the air knives 11a and 11b, is sprayed to the upper/lower surface of the substrate 1 slantingly at a predetermined incident angle in an opposite direction of the substrate moving direction. Thereby, the washing water is pushed away and removed from the upper surface of the substrate 1, which passes below the upper board 12, and the lower surface of the substrate 1, which passes above the lower board 14.

FIG. 2 is a side view including some sections showing another example of the substrate treatment apparatus according to the present invention. This example differs from the example shown in FIG. 1 in point of filling the space between the lower board 14 and the substrate 1 with the washing water, which is filled into the space between the upper board 12 and the substrate 1 and flows out from sides of the substrate 1, by adjusting the flow rate of the washing water supplied from the pipe 13 so that the pipe 15 is unnecessary. Other components are the same as those of the example shown in FIG. 1.

FIG. 3 is a side view including some sections showing another example of the substrate treatment apparatus according to the present invention. This example slopes the substrate at a predetermined angle from the horizontal in the substrate moving direction while moving the substrate. The substrate treatment apparatus comprises a plurality of rollers 20, air knives 21a and 21b, an upper board 22, a pipe 23, a lower board 24 and a pipe 25. The installation height of each roller 20 becomes higher as its installation position is forward to the substrate moving direction. Thereby, the rollers 20 slope the substrate 1 at the predetermined angle theta 1 from the horizontal in the substrate moving direction while moving the substrate 1. The air knives 21a and 21b, the upper board 22 and the lower board 24 are installed slantingly according to a slope of the substrate 1. Other components are the same as those of the example shown in FIG. 1.

According to the example shown in FIG. 3, the whole apparatus needs less floor area in the substrate moving direction since it slopes the substrate at the predetermined angle from the horizontal in the substrate moving direction while moving the substrate.

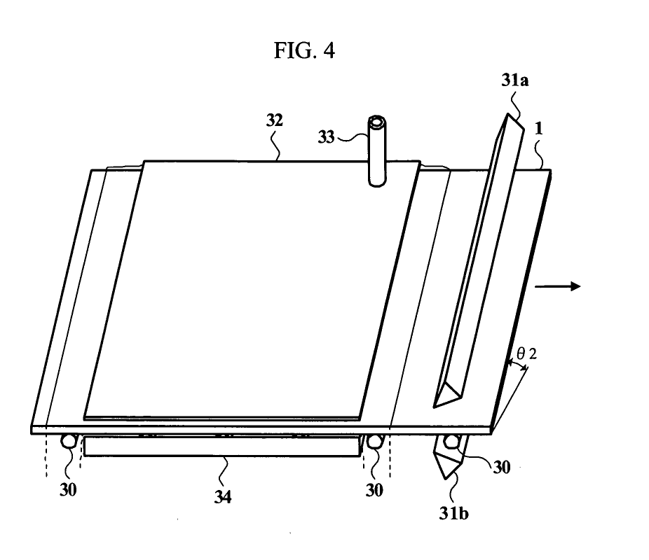

FIG. 4 shows an outline of another example of the substrate treatment apparatus according to the present invention. This example slopes the substrate at a predetermined angle from the horizontal in a direction perpendicular to the substrate moving direction while moving the substrate. The substrate treatment apparatus comprises a plurality of rollers 30, air knives 31a and 31b, an upper board 32, a pipe 33, a lower board 34 and a pipe 35. In FIG. 4, the pipe 35 is hidden behind the lower board 34 and not seen. Each roller 30 is installed slantingly so that its one end becomes higher than another end. Thereby, the rollers 30 slope the substrate 1 at the predetermined angle theta 2 from the horizontal in the direction perpendicular to the substrate moving direction while moving the substrate 1. The air knives 31a and 31b, the upper board 32 and the lower board 34 are installed slantingly according to a slope of the substrate 1. The pipe 33 shifts to a higher side of the sloped upper board 32, and the pipe 35 shifts to a higher side of the sloped upper board 34. Other components are the same as those of the example shown in FIG. 1.

According to the example shown in FIG. 4, the whole apparatus needs less floor area in the direction perpendicular to the substrate moving direction since it slopes the substrate at the predetermined angle from the horizontal in the direction perpendicular to the substrate moving direction while moving the substrate. Furthermore, for the example shown in FIG. 3, it is necessary to prevent a treatment liquid, which flows along the sloped substrate, from flowing into a former process when performing a chemical liquid treatment, such as development, etching, etc. By the example shown in FIG. 4, it becomes possible to easily collect the treatment liquid using the equipment in each process since the treatment liquid flows to a side portion of the substrate.

According to the examples shown in FIG. 3 and FIG. 4, the high washing effect is obtained by sloping the substrate at the predetermined angle from the horizontal while moving the substrate since the treatment liquid, such as a developing solution, etching solution, etc., does not stagnate on the surface of the substrate but it is efficiently replaced with the washing water. Furthermore, the high foreign matter removal effect is obtained since the washing water also does not stagnate on the surface of the substrate so that foreign matters, which float out from the surface of the substrate, hardly adhere to the surface of the substrate again.

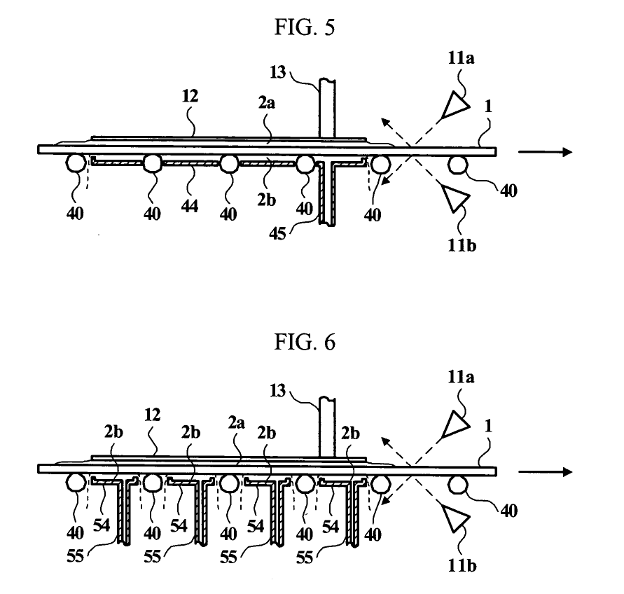

FIG. 5 is a side view including some sections showing another example of the substrate treatment apparatus according to the present invention. This example differs from the example shown in FIG. 1 in point of making a diameter of rollers 40 bigger and making a space between a lower board 44 and the substrate 1 smaller than the diameter of the rollers 40. On the lower board 44, openings for exposing the rollers 40 are prepared, and the pipe 45 is installed at a certain position, which is shifted to the substrate moving direction from the center of the lower board 44. The pipe 45 fills the space between the lower board 44 and the substrate 1 with the washing water 2b by supplying the washing water at a predetermined flow rate. Other components are the same as those of the example shown in FIG. 1.

FIG. 6 is a side view including some sections showing another example of the substrate treatment apparatus according to the present invention. This example differs from the example shown in FIG. 5 in point of preparing a plurality of lower board 54, which is arranged between two rollers 40. On each lower board 54, the pipe 55 is installed at a certain position, which is shifted to the substrate moving direction from the center of the lower board 54. Each pipe 55 fills a space between each lower board 54 and the substrate 1 with the washing water 2b by supplying the washing water at a predetermined flow rate. Other components are the same as those of the example shown in FIG. 1.

According to the examples explained above, by preparing the upper board 12, 22 or 32 the predetermined distance apart above the substrate 1 and filling the space between the upper board 12, 22 or 32 and the substrate with the washing water 2a, it becomes possible to form the washing water layer evenly on the upper surface of the substrate 1 using a less amount of the washing water. Moreover, since the upper surface of the substrate 1 is covered by the upper board 12, 22 or 32, drops of the washing water, which are blown away with the air from the air knife 11a, 21a or 31a, do not adhere to the upper surface of the substrate 1. Therefore, it becomes possible to prevent watermarks being generated.

In the same way, by preparing the lower board 14, 24, 34, 44 or 54 the predetermined distance apart below the substrate 1 and filling the space between the lower board 14, 24, 34, 44 or 54 and the substrate with the washing water 2b, it becomes possible to form the washing water layer evenly on the lower surface of the substrate 1 using a less amount of the washing water. Moreover, since the lower surface of the substrate 1 is covered by the lower board 14, 24, 34, 44 or 54, drops of the washing water, which are blown away with the air from the air knife 11b, 21b or 31b, do not adhere to the lower surface of the substrate 1. Therefore, it becomes possible to prevent the watermarks being generated.

In the examples explained above, a further effect is obtained by filling the space between the upper board 12, 22 or 32 and the substrate 1 or the space between the lower board 14, 24, 34, 44 or 54 and the substrate 1 with the washing water of a temperature higher than the normal temperature. Since the viscosity of the washing water becomes low, the washing water is easily pushed away from the upper/lower surface of the substrate 1 by the air from the air knife 11a, 11b, 21a, 21b, 31a or 31b. Moreover, since the vapor pressure head of the washing water becomes high, the washing water is easily vaporized from the upper/lower surface of the substrate 1. Therefore, it becomes possible to shorten the drying time and reduce drying stains.

The same effect is obtained by heating the washing water 2a, which is filled into the space between the upper board 12, 22 or 32 and the substrate 1, or the washing water 2b, which is filled into the space between the lower board 14, 24, 34, 44 or 54 and the substrate 1. A mechanism for heating the washing water 2a or 2b (a heater and the like, for example) can be installed in the upper board 12, 22 or 32, the lower board 14, 24, 34, 44 or 54, or both. Instead of installing the mechanism for heating the washing water 2a directly in the upper board 12, 22 or 32, the third flat component, which has the mechanism for heating the washing water 2a, may be prepared between the upper board 12, 22 or 32 and the substrate 1. Similarly, instead of installing the mechanism for heating the washing water 2b directly in the lower board 14, 24, 34, 44 or 54, the fourth flat component, which has the mechanism for heating the washing water 2b, may be prepared between the lower board 14, 24, 34, 44 or 54 and the substrate 1.

Moreover, by spraying the air of a temperature higher than the normal temperature from the air knife 11a, 11b, 21a, 21b, 31a or 31b, the washing water is easily vaporized from the upper/lower surface the substrate 1. Therefore, it becomes possible to shorten the drying time and reduce the drying stains.

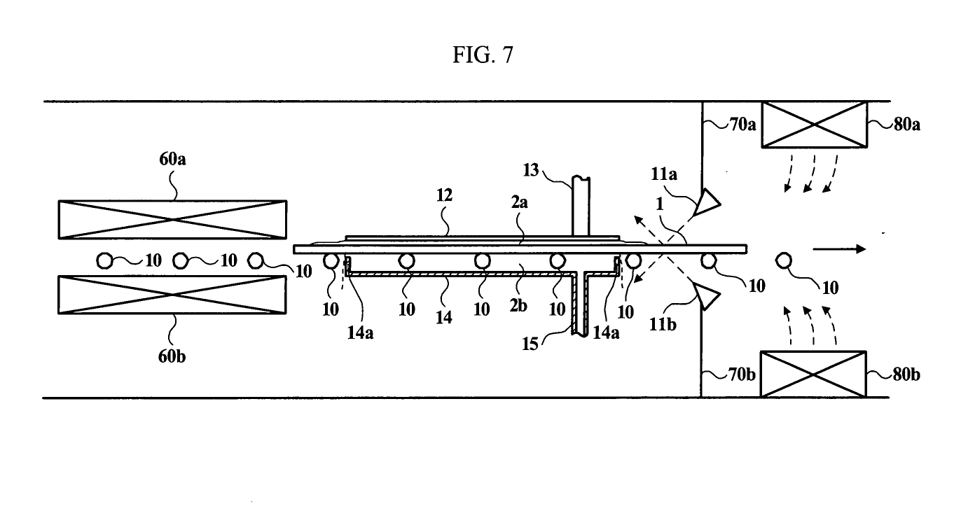

FIG. 7 is a side view including some sections showing another example of the substrate treatment apparatus according to the present invention. In this example, the example shown in FIG. 1 further comprises heaters 60a and 60b ahead of the upper board 12 and the lower board 14, and warm air suppliers 80a and 80b behind the air knives 11a and 11b. Other components are the same as those of the example shown in FIG. 1.

In this example, the pipe 13 fills the space between the upper board 12 and the substrate 1 with the washing water of a temperature higher than the normal temperature, and the pipe 15 fills the space between the lower board 14 and the substrate 1 with the washing water of the temperature higher than the normal temperature. Then, the air knife 11a sprays the air of a temperature higher than the normal temperature to the upper surface of the substrate 1, which passes below the upper board 12, and the air knife 11b sprays the air of the temperature higher than the normal temperature to the lower surface of the substrate 1, which passes above the lower board 14.

At this time, it is preferable that the temperature of the air, which is sprayed from the air knives 11a and 11b, is higher than the temperature of the washing water, which is filled into the space between the upper board 12 and the substrate 1 and the space between the lower board 14 and the substrate 1. In this example, when the temperature of the washing water, which is filled into the space between the upper board 12 and the substrate 1 and the space between the lower board 14 and the substrate 1, is approximately 40 degrees Celsius, the drying time becomes approximately 30 percent shorter than a case where the washing water is at the normal temperature. And when the temperature of the air, which is sprayed from the air knives 11a and 11b, is approximately 55 degrees Celsius, the drying time further becomes approximately 10 percent shorter than a case where the air is at the normal temperature.

When spraying the air from the air knife 11a or 11b, an air layer, which is drawn by the air of the air knife 11a or 11b from back of the air knife 11a or 11b, touches the upper/lower surface of the substrate 1. If this air layer is colder than the air of the air knife 11a or 11b, the shortening effect of the drying time will decrease. In this example, the warm air suppliers 80a and 80b are prepared behind the air knives 11a and 11b and partitioned by walls 70a and 70b. The warm air suppliers 80a and 80b generate the warm air of almost the same temperature to the air sprayed by the air knives 11a and 11b. Thereby, it becomes possible to prevent the shortening effect of the drying time decreasing and further reduce the drying stains.

Moreover, by heating the upper surface of the substrate 1 using the heater 60a, which is prepared ahead of the upper board 12, before the substrate 1 passes below the upper board 12, the washing water is easily vaporized from the heated upper surface of the substrate 1. In the same way, by heating the lower surface of the substrate 1 using the heater 60b, which is prepared ahead of the lower board 14, before the substrate 1 passes above the lower board 14, the washing water is easily vaporized from the heated lower surface of the substrate 1. Therefore, it becomes possible to shorten the drying time and further reduce the drying stains.

In addition, the heating of the upper/lower surface of the substrate 1 is not restricted before the substrate 1 passes below/above the upper/lower board 12 or 14, but it may be carried out during or after the substrate 1 passes below/above the upper/lower board 12 or 14.

Although one pipe 13, 23 or 33 is installed on the upper board 12, 22 or 32 in the examples explained above, two or more pipes 13, 23 or 33 may be installed depending on a size of the upper board 12, 22 or 32. Similarly, two or more pipes 15, 25, 35, 45, or 55 may be installed on the lower board 14, 24, 34, 44 or 54.

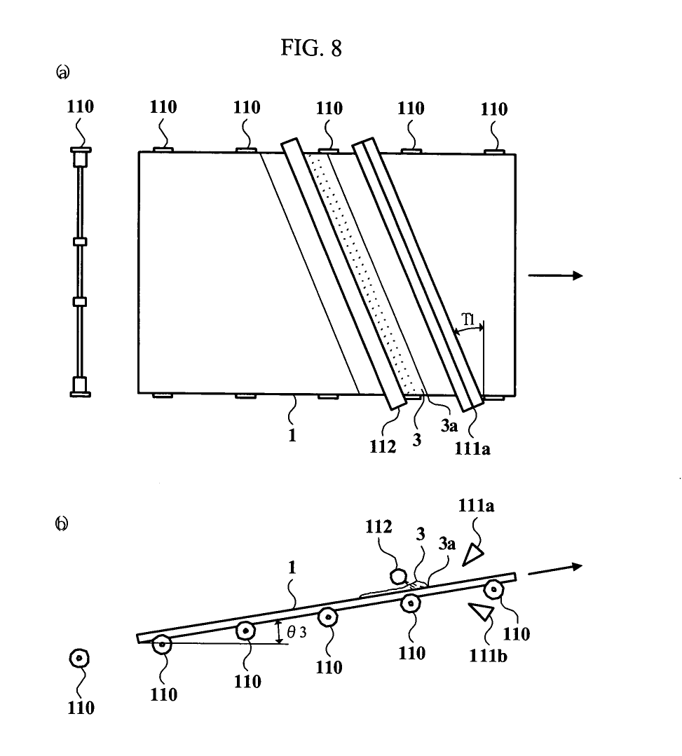

FIG. 8 shows another example of the substrate treatment apparatus according to the present invention, wherein (a) shows a top view and (b) shows a side view. This example applies the present invention to a sloping carry system, which slopes the substrate at a certain angle in the substrate moving direction while moving the substrate. The substrate treatment apparatus comprises a plurality of rollers 110, air knives 111a and 111b and a nozzle 112.

The substrate 1 is mounted on the rollers 110 and moved in the substrate moving direction shown by an arrow with the rotation of the rollers 110. Each roller 110 is arranged a certain distance apart each other in the substrate moving direction and rotated at a predetermined speed by the drive equipment, which is not illustrated. As shown in FIG. 8(b), the installation height of each roller 110 becomes higher as its installation position is forward to the substrate moving direction. Thereby, the rollers 110 slope the substrate 1 at the predetermined angle theta 3 from the horizontal in the substrate moving direction while moving the substrate 1. Each roller 110 has flanges on its both ends for guiding the sides of the substrate 1.

Above the substrate 1 mounted on the rollers 110, the air knife 111a is prepared through the width of the substrate 1 in the direction perpendicular to the substrate moving direction, wherein the air knife 111a is in parallel with the substrate 1. And below the substrate 1 mounted on the rollers 110, the air knife 111b is prepared in the same way. The air knives 111a and 111b are constituted of a long casing, for example, wherein a pressure room is formed inside the casing and a slit-shape air passage led to the pressure room is prepared through its length. The air is supplied to the air knives 111a and 111b from the air supply equipment, which is not illustrated, and the air knives 111a and 111b emit the air from an end of the air passage evenly through its length.

Moreover, above the substrate I mounted on the rollers 110, the nozzle 112 is prepared through the width of the substrate 1 in the direction perpendicular to the substrate moving direction, wherein the nozzle 112 is near the air knife 111a and in parallel with the air knife 111a. The nozzle 112 is constituted of a long pipe, for example, wherein a nozzle mouth is prepared in every certain length or as a slit through its length. The washing water is supplied to the nozzle 112 from the washing water supply equipment, which is not illustrated, and the nozzle 112 emits the washing water 2 from the nozzle mouth evenly through its length.

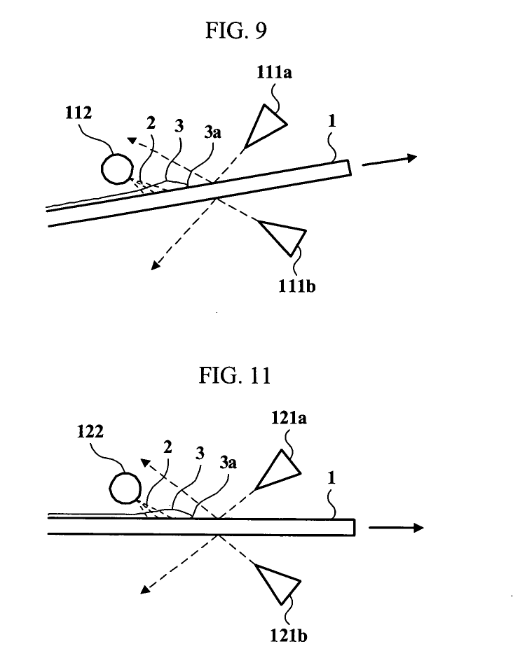

FIG. 9 shows an operation of the substrate treatment apparatus shown in FIG. 8. As shown by arrows of a broken line in the figure, the air, which is emitted from the air knives 111a and 111b, is sprayed to the upper/lower surface of the substrate 1 slantingly at a predetermined incident angle in an opposite direction of the substrate moving direction. On the other hand, the washing water 2, which is emitted from the nozzle 112, is supplied to the upper surface of the substrate 1 slantingly at a predetermined incident angle in an opposite direction of the air from the air knife 111a. On the upper surface of the substrate 1, a washing water layer 3 is formed through the width of the substrate 1 in the direction perpendicular to the substrate moving direction by the washing water 2, which is emitted from the nozzle 112. A boundary 3a of the formed washing water layer 3 appears at a position, where the power of a flow of the washing water 2 from the nozzle 112 to push the washing water layer 3, the power of the washing water layer 3 to move along a slope of the substrate 1 and the power of the air from the air knife 111a to push the washing water layer 3 away are balanced.

Beside the boundary 3a of the washing water layer 3 on the upper surface of the substrate 1, a side in the substrate moving direction becomes a dry area, where the washing water layer 3 is pushed away and removed by the air from the air knife 111a. On the other hand, in a non-dry area in an opposite side, the washing water layer 3 is always formed with the washing water 2, which is supplied from the nozzle 112. Therefore, even if the substrate 1 has the water repellency strongly on its upper surface, line-shape stains will not be generated unlike before since the washing water layer 3 has being formed on the upper surface of the substrate 1 just before drying. Moreover, the foreign matters do not remain unlike before along traces of small drops moved. And the high washing effect and the high foreign matter removal effect are obtained by sloping the substrate 1 at the predetermined angle theta 3 from the horizontal while moving the substrate 1.

As shown in FIG. 8(a), the air knife 111a is slanted at a predetermined angle T1 from the direction perpendicular to the substrate moving direction. The nozzle 112 is also slanted in the same way. Thereby, since the washing water, which forms the washing water layer 3, is pushed away by the air from the air knife 111a, moved aslant the upper surface of the substrate 1 and blown away not only from an end portion but also from the side portion of the substrate 1, the washing water is removed efficiently.

According to the example shown in FIG. 8, the whole apparatus needs less floor area in the substrate moving direction since it slopes the substrate at the predetermined angle in the substrate moving direction while moving the substrate.

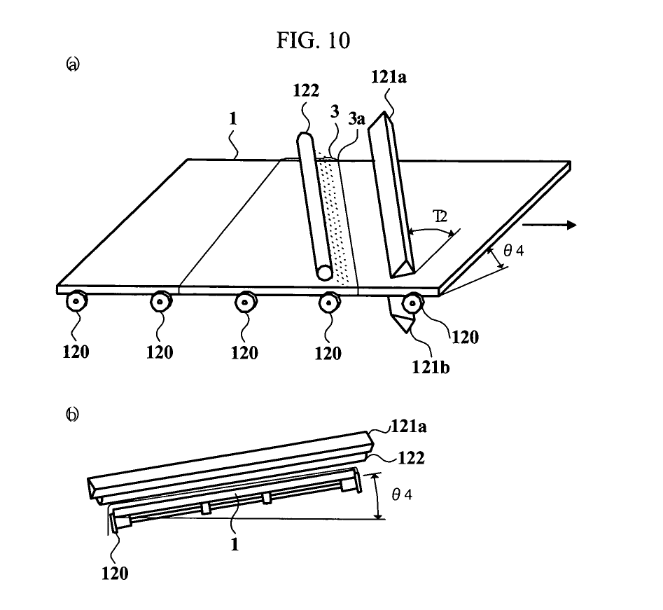

FIG. 10 shows another example of the substrate treatment apparatus according to the present invention, wherein (a) shows an outline and (b) shows a front view. This example applies the present invention to a sloping carry system, which slopes the substrate at a predetermined angle in the direction perpendicular to the substrate moving direction while moving the substrate. The substrate treatment apparatus comprises a plurality of rollers 120, air knives 121a and 121b and a nozzle 122.

The substrate 1 is mounted on the rollers 120 and moved in the substrate moving direction shown by an arrow with the rotation of the rollers 120. Each roller 120 is arranged a certain distance apart each other in the substrate moving direction and rotated at a predetermined speed by the drive equipment, which is not illustrated. As shown in FIG. 10(b), each roller 120 is installed slantingly so that its one end becomes higher than another end. Thereby, the rollers 120 slope the substrate 1 at the predetermined angle theta 4 from the horizontal in the direction perpendicular to the substrate moving direction while moving the substrate 1. Each roller 120 has flanges on its both ends for guiding the sides of the substrate 1.

Above the substrate 1 mounted on the rollers 120, the air knife 121a is prepared through the width of the substrate 1 in the direction perpendicular to the substrate moving direction, wherein the air knife 121a is in parallel with the substrate 1. And below the substrate 1 mounted on the rollers 120, the air knife 121b is prepared in the same way. The air knives 121a and 121b are constituted similarly to the air knives 111a and 111b in FIG. 8. In FIG. 10(b), an illustration of the air knife 121b is omitted.

Moreover, above the substrate 1 mounted on the rollers 120, the nozzle 122 is prepared through the width of the substrate 1 in the direction perpendicular to the substrate moving direction, wherein the nozzle 122 is near the air knife 121a and in parallel with the air knife 121a. The nozzle 122 is constituted similarly to the nozzle 112 in FIG. 8.

FIG. 11 shows an operation of the substrate treatment apparatus shown in FIG. 10. As shown by arrows of a broken line in the figure, the air, which is emitted from the air knives 121a and 121b, is sprayed to the upper/lower surface of the substrate 1 slantingly at a predetermined incident angle in an opposite direction of the substrate moving direction. On the other hand, the washing water 2, which is emitted from the nozzle 122, is supplied to the upper surface of the substrate 1 slantingly at a predetermined incident angle in an opposite direction of the air from the air knife 121a. On the upper surface of the substrate 1, a washing water layer 3 is formed through the width of the substrate 1 in the direction perpendicular to the substrate moving direction by the washing water 2, which is emitted from the nozzle 122. A boundary 3a of the formed washing water layer 3 appears at a position, where the power of a flow of the washing water 2 from the nozzle 122 to push the washing water layer 3, the power of the washing water layer 3 to move along a slope of the substrate 1 and the power of the air from the air knife 121a to push the washing water layer 3 away are balanced.

Beside the boundary 3a of the washing water layer 3 on the upper surface of the substrate 1, a side in the substrate moving direction becomes a dry area, where the washing water layer 3 is pushed away and removed by the air from the air knife 121a. On the other hand, in a non-dry area in an opposite side, the washing water layer 3 is always formed with the washing water 2, which is supplied from the nozzle 122. Therefore, even if the substrate 1 has the water repellency strongly on its upper surface, the line-shape stains will not be generated unlike before since the washing water layer 3 has being formed on the upper surface of the substrate 1 just before drying. Moreover, the foreign matters do not remain unlike before along the traces of the small drops moved. And the high washing effect and the high foreign matter removal effect are obtained by sloping the substrate 1 at the predetermined angle theta 4 from the horizontal while moving the substrate 1.

As shown in FIG. 10(a), the air knife 121a is slanted at a predetermined angle T2 from the direction perpendicular to the substrate moving direction. The nozzle 122 is also slanted in the same way. Thereby, since the washing water, which forms the washing water layer 3, is pushed away by the air from the air knife 121a and moved aslant the upper surface of the substrate 1 with the help of a slope of the substrate 1, the washing water is removed efficiently.

According to the example shown in FIG. 10, the whole apparatus needs less floor area in the direction perpendicular to the substrate moving direction since it slopes the substrate at the predetermined angle in the direction perpendicular to the substrate moving direction while moving the substrate. Furthermore, for the example shown in FIG. 8, it is necessary to prevent the treatment liquid, which flows along the sloped substrate, from flowing into the former process when performing the chemical liquid treatment, such as development, etching, etc. By the example shown in FIG. 10, it becomes possible to easily collect the treatment liquid using the equipment in each process since the treatment liquid flows to the side portion of the substrate.

In the examples shown in FIG. 8 and FIG. 10, the position, where the boundary 3a of the washing water layer 3 appears, can be adjusted so as to obtain the best washing effect, the best foreign matter removal effect and the best drying effect by adjusting a moving speed of the substrate 1, the slope angle theta 3 or theta 4 of the substrate 1, a flow rate and a flow velocity of the air emitted from the air knife 111a or 121a, a flow rate and a flow velocity of the washing water emitted from the nozzle 112 or 122, a direction of the nozzle 112 or 122 (the incident angle of the washing water 2), a distance between the nozzle 112 or 122 and the substrate 1, etc.

In the examples shown in FIG. 8 and FIG. 10, a further effect is obtained by supplying the washing water of a temperature higher than the normal temperature from the nozzle 112 or 122 to the upper surface of the substrate 1. Since the viscosity of the washing water becomes low, the washing water is easily pushed away from the upper surface of the substrate 1 by the air from the air knife 111a or 121a. Moreover, since the vapor pressure head of the washing water becomes high, the washing water is easily vaporized from the upper surface the substrate 1. Therefore, it becomes possible to shorten the drying time and reduce the drying stains.

Moreover, by spraying the air of a temperature higher than the normal temperature from the air knife 111a or 121a, the washing water is easily vaporized from the upper surface the substrate 1. Therefore, it becomes possible to shorten the drying time and reduce the drying stains.

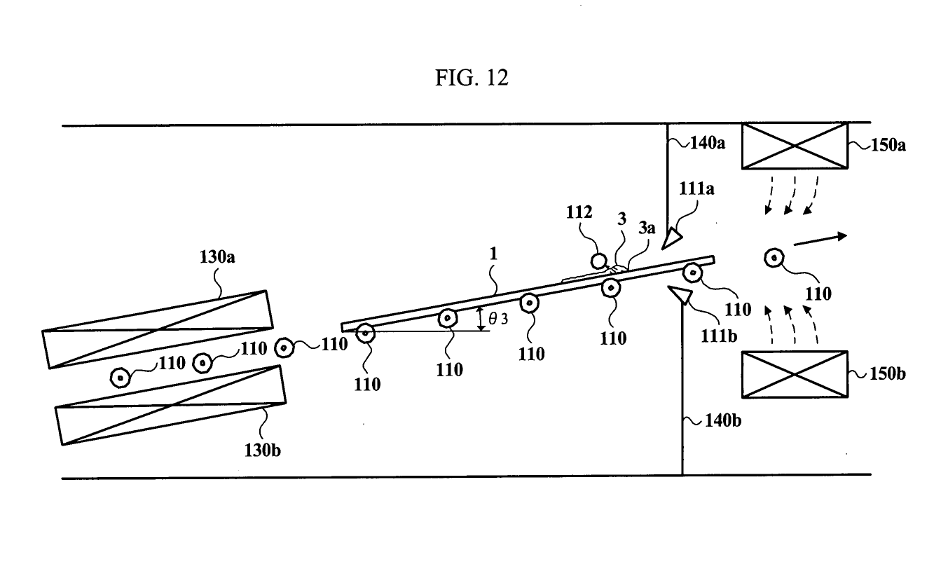

FIG. 12 is a side view showing another example of the substrate treatment apparatus according to the present invention. In this example, the example shown in FIG. 8 further comprises heaters 130a and 130b ahead of the nozzle 112, and warm air suppliers 150a and 150b behind the air knives 111a and 111b. Other components are the same as those of the example shown in FIG. 1.

In this example, the nozzle 112 supplies the washing water of a temperature higher than the normal temperature to the upper surface of the substrate 1. Then, the air knives 111a and 111b spray the air of a temperature higher than the normal temperature to the upper surface and the lower surface of the substrate 1.

At this time, it is preferable that the temperature of the air, which is sprayed from the air knives 111a and 111b, is higher than the temperature of the washing water, which is supplied from the nozzle 112. In this example, when the temperature of the washing water, which is supplied from the nozzle 112, is approximately 40 degrees Celsius, the drying time becomes approximately 30 percent shorter than a case where the washing water is at the normal temperature. And when the temperature of the air, which is sprayed from the air knives 111a and 111b, is approximately 55 degrees Celsius, the drying time further becomes approximately 10 percent shorter than a case where the air is at the normal temperature.

When spraying the air from the air knife 111a or 111b, an air layer, which is drawn by the air of the air knife 111a or 111b from back of the air knife 111a or 111b, touches the upper/lower surface of the substrate 1. If this air layer is colder than the air of the air knife 111a or 111b, the shortening effect of the drying time will decrease. In this example, the warm air suppliers 150a and 150b are prepared behind the air knives 111a and 111b and partitioned by walls 140a and 140b. The warm air suppliers 150a and 150b generate the warm air of almost the same temperature to the air sprayed by the air knives 111a and 111b. Thereby, it becomes possible to prevent the shortening effect of the drying time decreasing and further reduce the drying stains.

Moreover, by heating the upper surface and the lower surface of the substrate 1 using the heaters 130a and 130b, which are prepared ahead of the nozzle 112, before supplying the washing water from the nozzle 112, the washing water is easily vaporized from the heated upper surface and the heated lower surface of the substrate 1. Therefore, it becomes possible to shorten the drying time and further reduce the drying stains.

In addition, the heating of the upper/lower surface of the substrate 1 is not restricted before supplying the washing water to the upper/lower surface of the substrate 1, but it may be carried out during or after supplying the washing water to the upper/lower surface of the substrate 1.

Although the examples explained above use the washing water, the present invention is not restricted to the washing water but applicable to the chemical liquid treatments of the substrate using various treatment liquids. Also the present invention is not restricted to panel substrates for flat panel displays but applicable to various substrates including semiconductor wafers.

By drying the substrate using the substrate treatment apparatuses explained above or substrate treatment methods employing them, it becomes possible to reduce the drying stains and the foreign matters on the surface of the substrate and manufacture a high quality substrate.

1. A substrate treatment apparatus comprising:
a substrate moving means for moving a substrate,
the first flat component prepared a predetermined distance above the substrate, said substrate is moved by said substrate moving means,
the first treatment liquid passage for filling a space between said first flat component and the substrate with a treatment liquid, and
the first air knife for spraying air to an upper surface of the substrate, which passes below said first flat component.

2. The substrate treatment apparatus according to claim 1, wherein said first treatment liquid passage fills the space between said first flat component and the substrate with the treatment liquid of a temperature higher than the normal temperature.

3. The substrate treatment apparatus according to claim 1 further comprising means for heating the treatment liquid which is filled into the space between said first flat component and the substrate.

4. The substrate treatment apparatus according to claim 1, wherein said first air knife sprays the air of a temperature higher than the normal temperature.

5. The substrate treatment apparatus according to claim 4 further comprising means for supplying the warm air to said first air knife.

6. The substrate treatment apparatus according to claim 1 further comprising means for heating the upper surface of the substrate before, during or after the substrate passes below said first flat component.

7. The substrate treatment apparatus according to claim 1 further comprising a second flat component prepared a predetermined distance below the substrate, the substrate moved by said substrate moving means, a second treatment liquid passage for filling a space between said second flat component and the substrate with the treatment liquid, and a second air knife for spraying the air to a lower surface of the substrate, which passes above said second flat component.

8. The substrate treatment apparatus according to claim 7, wherein said first treatment liquid passage also serves as said second treatment liquid passage.

9. The substrate treatment apparatus according to claim 7, wherein said second treatment liquid passage fills the space between said second flat component and the substrate with the treatment liquid of a temperature higher than the normal temperature.

10. The substrate treatment apparatus according to claim 7 further comprising means for heating the treatment liquid which is filled into the space between said second flat component and the substrate.

11. The substrate treatment apparatus according to claim 7, wherein said second air knife sprays air of a temperature higher than the normal temperature.

12. The substrate treatment apparatus according to claim 11 further comprising means prepared for supplying the warm air to said second air knife.

13. The substrate treatment apparatus according to claim 7 further comprising means for heating the lower surface of the substrate before, during or after the substrate passes above said second flat component.

14. The substrate treatment apparatus according to claim 1, wherein said substrate moving means slopes the substrate at a predetermined angle from horizontal in a substrate moving direction while moving the substrate.

15. The substrate treatment apparatus according to claim 1, wherein said substrate moving means slopes the substrate at a predetermined angle from horizontal in a direction perpendicular to a substrate moving direction while moving the substrate.

16. A substrate treatment method characterized by preparing a first flat component a predetermined distance apart above a substrate, filling a space between said first flat component and the substrate with a treatment liquid, and spraying air to an upper surface of the substrate, which passes below said first flat component, from the first air knife while moving the substrate.

17. The substrate treatment method according to claim 16 characterized by filling the space between said first flat component and the substrate with the treatment liquid of a temperature higher than the normal temperature.

18. The substrate treatment method according to claim 16 characterized by heating the treatment liquid, which is filled into the space between said first flat component and the substrate.

19. The substrate treatment method according to claim 16 characterized by spraying the air of a temperature higher than the normal temperature from said first air knife.

20. The substrate treatment method according to claim 19 characterized by supplying the warm air from back of said first air knife.

21. The substrate treatment method according to claim 16 characterized by heating the upper surface of the substrate before, during or after the substrate passes below said first flat component.

22. The substrate treatment method according to claim 16 characterized by preparing the second flat component a predetermined distance apart below the substrate, filling a space between said second flat component and the substrate with the treatment liquid, and spraying the air to a lower surface of the substrate, which passes above said second flat component, from the second air knife.

23. The substrate treatment method according to claim 22 characterized by filling the space between said second flat component and the substrate with the treatment liquid of a temperature higher than the normal temperature.

24. The substrate treatment method according to claim 22 characterized by heating the treatment liquid, which is filled into the space between said second flat component and the substrate.

25. The substrate treatment method according to claim 22 characterized by spraying the air of a temperature higher than the normal temperature from said second air knife.

26. The substrate treatment method according to claim 25 characterized by supplying the warm air from back of said second air knife.

27. The substrate treatment method according to claim 22 characterized by heating the lower surface of the substrate before, during or after the substrate passes above said second flat component.

28. The substrate treatment method according to claim 16 characterized by sloping the substrate at a predetermined angle from horizontal in a substrate moving direction while moving the substrate.

29. The substrate treatment method according to claim 16 characterized by sloping the substrate at a predetermined angle from horizontal in a direction perpendicular to a substrate moving direction while moving the substrate.

30. A substrate manufacturing method characterized by drying a substrate using the substrate treatment apparatus according to claim 1.

31. A substrate manufacturing method characterized by drying a substrate using the substrate treatment method according to claim 16.

32. A substrate treatment apparatus comprising:
a substrate moving means for moving a substrate, which has a strong water repellency on its surface, with the substrate sloped at a predetermined angle from the horizontal,
an air knife for spraying the air to the surface of the substrate, which is moved by said substrate moving means, slantingly at a predetermined incident angle, and
a treatment liquid layer forming means prepared near said air knife for supplying a treatment liquid to the surface of the substrate slantingly at a predetermined incident angle in an opposite direction of the air from said air knife so as to form a treatment liquid layer on the surface of the substrate.

33. The substrate treatment apparatus according to claim 32, wherein said treatment liquid layer forming means supplies the treatment liquid of a temperature higher than the normal temperature to the surface of the substrate.

34. The substrate treatment apparatus according to claim 32, wherein said air knife sprays the air of a temperature higher than the normal temperature to the surface of the substrate.

35. The substrate treatment apparatus according to claim 34 further comprising means prepared behind said air knife for supplying the warm air.

36. The substrate treatment apparatus according to claim 32 further comprising means for heating the surface of the substrate before, during or after said treatment liquid layer forming means supplies the treatment liquid to the surface of the substrate.

37. The substrate treatment apparatus according to claim 32, wherein said substrate moving means slopes the substrate at the predetermined angle in a substrate moving direction while moving the substrate.

38. The substrate treatment apparatus according to claim 32, wherein said substrate moving means slopes the substrate at the predetermined angle in a direction perpendicular to a substrate moving direction while moving the substrate.

39. A substrate treatment method characterized by spraying the air from an air knife to a surface of a substrate slantingly at a predetermined incident angle, and supplying a treatment liquid near from said air knife to the surface of the substrate slantingly at a predetermined incident angle in an opposite direction of the air from said air knife so as to form a treatment liquid layer on the surface of the substrate while moving the substrate, which has a strong water repellency on its surface, with the substrate sloped at a predetermined angle from the horizontal.

40. The substrate treatment method according to claim 39 characterized by supplying the treatment liquid of a temperature higher than the normal temperature to the surface of the substrate.

41. The substrate treatment method according to claim 39 characterized by spraying the air of a temperature higher than the normal temperature from said air knife to the surface of the substrate.

42. The substrate treatment method according to claim 41 characterized by supplying the warm air from back of said air knife.

43. The substrate treatment method according to claim 39 characterized by heating the surface of the substrate before, during or after supplying the treatment liquid to the surface of the substrate.

44. The substrate treatment method according to claim 39 characterized by sloping the substrate at the predetermined angle in a substrate moving direction while moving the substrate.

45. The substrate treatment method according to claim 39 characterized by sloping the substrate at the predetermined angle in a direction perpendicular to a substrate moving direction while moving the substrate.

46. A substrate manufacturing method characterized by drying a substrate using the substrate treatment apparatus according to claim 32.

47. A substrate manufacturing method characterized by drying a substrate using the substrate treatment method according to claim 39.
